(19) United States
(12) Patent Application Publication
(10) Pub. No.: US 2013/0029450 A1
(43) Pub. Date: Jan. 31, 2013

(54) METHOD FOR MANUFACTURING SOLAR CELL

(71) Applicants: Chae Hwan Jeong, Gwangju (KR); Jong Ho Lee, Gwangju (KR); Ho Sung Kim, Gwangju (KR); Jin Hyeok Kim, Gwangju (KR); Suk Ho Lee, Gwangju (KR)

(72) Inventors: Chae Hwan Jeong, Gwangju (KR); Jong Ho Lee, Gwangju (KR); Ho Sung Kim, Gwangju (KR); Jin Hyeok Kim, Gwangju (KR); Suk Ho Lee, Gwangju (KR)

(73) Assignee: Korea Institute of Industrial Technology, Chungcheongnam-do (KR)

(21) Appl. No.: 13/641,190

(22) PCT Filed: Apr. 19, 2011
(86) PCT No.: PCT/KR11/02797

§ 371 Date: Oct. 15, 2012

(30) Foreign Application Priority Data
Apr. 19, 2010 (KR) 10-2010-0035928
Apr. 19, 2010 (KR) 10-2010-0035929

(51) Int. Cl. H01L 31/18

(52) U.S. Cl. 438/72; 257/E31.124

(57) ABSTRACT

The present invention provides a method for manufacturing a solar cell capable of suppressing volatilization of selenium and deformation of a substrate during a manufacturing process. According to the present invention, the method for manufacturing the solar cell comprises the steps of: providing a substrate; forming a rear electrode on the substrate; forming a precursor film for a light absorption film on the rear electrode; forming a light absorption film by progressing a crystallization process for the precursor film for the light absorption film; forming a buffer film on the light absorption film; forming a window film on the buffer film, and forming an anti-reflection film on the window film; and partially patterning the anti-reflection film, and forming a grid electrode in a patterned area. Said precursor film for the light absorption film includes Cu—Zn—Sn—S (Cu₂ZnSnS₄), CuInSe₂, CuInS₂, Cu(InGa)Se₂, or Cu(InGa)S₂. Further, a Cu—Zn—Sn—S (Cu₂ZnSnS₄) precursor film, a CuInSe₂ precursor film, a CuInS₂ precursor film, and a Cu (InGa)Se₂ precursor film or a Cu(InGa)S₂ precursor film can have a multi-layer structure of each component or a single-layer structure having compounds of the components. Said crystallization step for the precursor film is progressed through an electron-beam irradiation process.

### TECHNICAL FIELD

Embodiments relate to a method of manufacturing a solar cell, and more particularly, to a method of manufacturing a Cu—Zn—Sn—S (CZTS) solar cell, a CuInSe₂ or CuInS₂ (CIS) solar cell, and a Cu(InGa)Se₂ or Cu(InGa)S₂ (CIGS) solar cell.

### BACKGROUND ART

A solar cell is a device directly converting solar energy into electrical energy and may be broadly classified as a silicon-based solar cell, a compound-based solar cell, and an organic-based solar cell according to a material used therein.

The silicon-based solar cell is classified as a single crystal silicon solar cell, a polycrystalline silicon solar cell, and an amorphous silicon solar cell, and the compound-based solar cell is classified as a GaAs, InP, or CdTe solar cell, a CuInSe₂ (copper-indium-diselenide) or CuInS₂ (hereinafter, referred to as “CIS”) solar cell, a Cu(InGa)Se₂ (copper-indium-gallium-selenium) or Cu(InGa)S₂ (hereinafter, referred to as “CIGS”) solar cell, and a Cu₂ZnSnS₄ (copper-zinc-tin-sulfur; hereinafter, referred to as “CZTS”) solar cell.

Also, the organic-based solar cell may be classified as an organic molecular solar cell, an organic-inorganic composite solar cell, and a dye-sensitized solar cell.

Among various solar cells described above, the single crystal silicon solar cell and the polycrystalline silicon solar cell include a light absorption layer on their substrates and thus, may be relatively unfavorable in terms of cost reduction.

Since the amorphous silicon solar cell includes a light absorption layer as a thin film, the amorphous silicon solar cell may be manufactured to have a thickness of about 1/100 of that of a crystalline silicon solar cell. However, the amorphous silicon solar cell may have an efficiency lower than that of a single crystal silicon solar cell and the efficiency may rapidly decrease when exposed to light.

The organic-based solar cell may have the same limitations as those of the amorphous silicon solar cell.

The compound-based solar cells have been developed in order to compensate for such limitations. The compound-based solar cells, such as a CZTS solar cell, a CIS solar cell, and a CIGS solar cell, have the best conversion efficiency among thin-film type solar cells. However, such conversion efficiency is obtained in laboratories and thus, various matters must be considered in order to commercialize the CZTS solar cell, the CIS solar cell, and the CIGS solar cell as a power application.

Meanwhile, in processes of manufacturing CIS and CIGS solar cells, a phenomenon, in which a substrate is deformed due to heat and selenium or sulfur, a component of the light absorption layer, is volatized due to heat, may occur in an operation of forming a light absorption layer. The deformation of the substrate and changes in a compositional ratio of components caused by the volatilization of selenium or sulfur may act as a main factor in decreasing functions of the CIS solar cell and the CIGS solar cell.

Similarly, in a process of manufacturing a CZTS solar cell, a phenomenon, in which a substrate is deformed due to heat or sulfur, a component of the light absorption layer, is volatized due to heat, may occur in an operation of forming a light absorption layer. The deformation of the substrate and changes in a compositional ratio of components caused by the volatilization of sulfur may decrease a function of the CZTS solar cell.

### DISCLOSURE OF THE INVENTION

### Technical Problem

An aspect of the present invention provides a method of manufacturing a solar cell able to prevent deformation of a substrate and inhibit volatilization of sulfur or selenium among components of a light absorption layer during a manufacturing process.

### Technical Solution

According to at least one of embodiments, a method of manufacturing a solar cell includes: providing a substrate; forming a rear electrode on the substrate; forming a precursor layer for a light absorption layer on the rear electrode; performing a crystallization process on the precursor layer for a light absorption layer to form a light absorption layer; forming a buffer layer on the light absorption layer; forming a window layer on the buffer layer and forming an anti-reflective layer on the window layer; and patterning a portion of the anti-reflective layer to form a grid electrode in a patterned area.

Herein, the precursor layer for a light absorption layer may be formed of any one of Cu₂ZnSnS₄, CuInSe₂, CuInS₂, Cu(InGa)Se₂, and Cu(InGa)S₂, and in particular, a Cu₂ZnSnS₄ layer, a CuInSe₂ precursor layer, a CuInS₂ precursor layer, a Cu(InGa)Se₂ precursor layer, or a Cu(InGa)S₂ precursor layer may have a multilayer structure of each component or a single layer structure formed of a compound of components.

The crystallization process of the precursor layer may be performed through an electron beam irradiation process.

### Advantageous Effects

A method of manufacturing a solar cell according to the present invention may have an effect of inhibiting deformation of a substrate and volatilization of sulfur or selenium among components of a light absorption layer in an operation of forming the light absorption layer through an electron beam deposition method.

### BRIEF DESCRIPTION OF THE DRAWINGS

FIG. 1 is a schematic view illustrating structures of a Cu—Zn—Sn—S (Cu₂ZnSnS₄) solar cell, a CuInS₂ or Cu(InGa)Se₂ solar cell, and a Cu(InGa)S₂ solar cell according to an embodiment;

FIGS. 2A through 2G illustrate a process for manufacturing the solar cells shown in FIG. 1;

FIGS. 3A and 3B are photographs showing a Cu(InGa)Se₂ precursor layer formed on a glass substrate, in which FIG. 3A illustrates the Cu(InGa)Se₂ precursor layer before irradiation with an electron beam and FIG. 3B illustrates the Cu(InGa)Se₂ precursor layer after the irradiation with an electron beam for 20 seconds; and

FIG. 4 is a graph comparing intensities of the precursor layers according to an angle before the irradiation with an electron beam and after the irradiation with an electron beam for 20 seconds.

### MODE FOR CARRYING OUT THE INVENTION

Hereinafter, a method of manufacturing a solar cell according to the present invention will be described in detail.

FIG. 1 is a schematic view illustrating structures of a Cu—Zn—Sn—S (Cu₂ZnSnS₄; hereinafter, referred to as “CZTS”) solar cell, a CuInSe₂ or CuInS₂ (hereinafter, referred to as “CIS”) solar cell, and a Cu(InGa)Se₂ or Cu(InGa)S₂ (hereinafter, referred to as “CIGS”) solar cell.

The CZTS solar cell, the CIS solar cell, and the CIGS solar cell have the same structure. That is, each of the CZTS solar cell, the CIS solar cell, and the CIGS solar cell has a structure, in which a rear electrode 20, a light absorption layer 30, a buffer layer 40, a window layer 50, and an anti-reflective layer 60 are sequentially formed on a substrate 10, and includes a grid electrode 70 formed in a patterned area of the anti-reflective layer 60.

Each component of the solar cell will be described in detail below.

### Substrate 10

The substrate 10 may be formed of glass and may be manufactured by using ceramic, such as alumina as well as glass, a metallic material such as stainless steel and a Cu tape, and a polymer.

Low cost soda-lime glass may be used as a material for the glass substrate. Also, a flexible polymer material, such as polyimide, or a stainless steel thin sheet may be used as a material for the substrate 10.

### Rear Electrode 20

Molybdenum (Mo) may be used as the rear electrode 20 formed on the substrate 10.

Molybdenum has high electrical conductivity, forms an ohmic contact with a Cu—Zn—Sn—S (Cu₂ZnSnS₄) light absorption layer to be described later, and has high-temperature stability in a sulfur (S) atmosphere.

Also, molybdenum forms an ohmic contact with a CuInSe₂ light absorption layer or a CuInS₂ light absorption layer to be described later, and has high-temperature stability in a selenium (Se) or sulfur (S) atmosphere.

A molybdenum thin film as an electrode may have low resistivity and may also have excellent adhesion to the glass substrate so as not to generate a delamination phenomenon due to the difference in thermal expansion coefficients. The molybdenum thin film 20 may be formed through a direct current (DC) sputtering process.

### Light Absorption Layer 30

The light absorption layer 30 formed on the rear electrode is a p-type semiconductor actually absorbing light.

In a CZTS solar cell, the light absorption layer 30 is formed of Cu—Zn—Sn—S (e.g., Cu₂ZnSnS₄). Cu₂ZnSnS₄ has an energy bandgap of 1.0 eV or more and has the highest light absorption coefficient among semiconductors. Also, since Cu₂ZnSnS₄ is relatively stable, a layer formed of such material may be relatively ideal as a light absorption layer of a solar cell.

Since a CZTS thin film as a light absorption layer is a multi-component compound, a manufacturing process is relatively complicated. A physical method of manufacturing the CZTS thin film includes evaporation and sputtering plus selenization, and a chemical method thereof includes electroplating. In each method, various manufacturing methods may be used according to types of a starting material (metal, binary compound, etc.).

Meanwhile, a CuInSe₂ layer or a CuInS₂ layer in a CIS solar cell and a Cu(InGa)Se₂ layer or a Cu(InGa)S₂ layer in a CIGS solar cell function as the light absorption layer 30. CuInSe₂, CuInS₂, Cu(InGa)Se₂, and Cu(InGa)S₂ have an energy bandgap of 1.0 eV or more and have the highest light absorption coefficient among semiconductors. Also, since CuInSe₂, CuInS₂, Cu(InGa)Se₂, and Cu(InGa)S₂ are relatively stable, a layer formed of such materials may be relatively ideal as a light absorption layer of a solar cell.

Since CIS thin film and CIGS thin film as light absorption layers are multi-component compounds, manufacturing processes are relatively complicated. A physical method of manufacturing CIS and CIGS thin films includes evaporation and sputtering plus selenization, and a chemical method thereof includes electroplating. In each method, various manufacturing methods may be used according to types of a starting material (metal, binary compound, etc.). A co-evaporation method known to obtain the best efficiency uses four metal elements (copper (Cu), indium (In), gallium (Ga), and Se) as a starting material.

### Buffer Layer 40

A p-type semiconductor Cu₂ZnSnS₄ thin film (light absorption layer) in a CZTS solar cell, a p-type semiconductor CuInSe₂ thin film or CuInS₂ thin film (light absorption layer) in a CIS solar cell, and a p-type semiconductor Cu(InGa)Se₂ thin film or a Cu(InGa)S₂ thin film (light absorption layer) in a CIGS solar cell form p-n junctions with a n-type semiconductor zinc oxide (ZnO) thin film used as a window layer described below.

However, since two materials have large differences in lattice constants and energy bandgaps, the buffer layer 40 having an energy bandgap between those of two materials is required in order to form a good contact. Cadmium sulfide (CdS) may be used as a material for the buffer layer 40 of a solar cell.

### Window Layer 50

As described above, the widow layer 50 as an n-type semiconductor forms a p-n junction with a light absorption layer 40 (CZTS layer, CIS layer, or CIGS layer) and functions as a front transparent electrode of a solar cell.

Therefore, the window layer 50 is formed of a material having high optical transmittance and excellent electrical conductivity, such as ZnO. Zinc oxide has an energy bandgap of about 3.3 eV and has a high degree of optical transmission of 80% or more.

### Anti-reflective Layer 60 and Grid Electrode 70

An efficiency of a solar cell may be improved to about 1% when a reflective loss of sunlight incident on the solar cell is reduced. In order to improve the efficiency of the solar cell, the anti-reflective layer 60 is formed on the window layer 50 and magnesium fluoride (MgF₂) is generally used as a material for the anti-reflective layer 60 inhibiting the reflection of the sunlight.

The grid electrode 70 acts to collect current on a surface of the solar cell and is formed of aluminum (Al) or nickel/aluminum (Ni/Al). The grid electrode 70 is formed in a patterned area of the anti-reflective layer 60.

When the sunlight is incident on the solar cell having the foregoing configuration, electron-hole pairs are generated between a p-type semiconductor light absorption layer 30 (i.e., a Cu₂ZnSnS₄ thin film in a CZTS solar cell, a CuInSe₂ thin film or a CuInS₂ thin film in a CIS solar cell, and a Cu(InGa)Se₂ thin film or a Cu(InGa)S₂ thin film in a CIGS solar cell) and a n-type semiconductor window layer 50. The generated electrons gather at the window layer 60 and the generated holes gather at the light absorption layer 30, and thus, a photovoltage is generated.

In this state, a current flows when an electrical load is connected to the substrate 10 and the grid electrode 70.

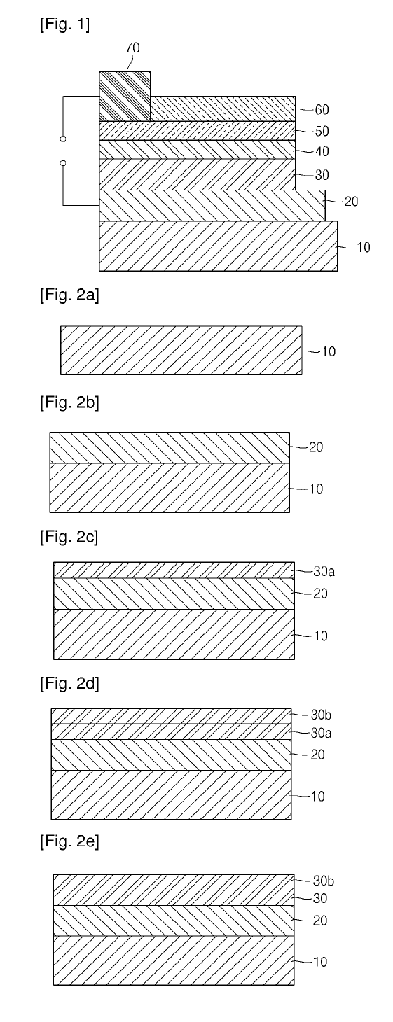

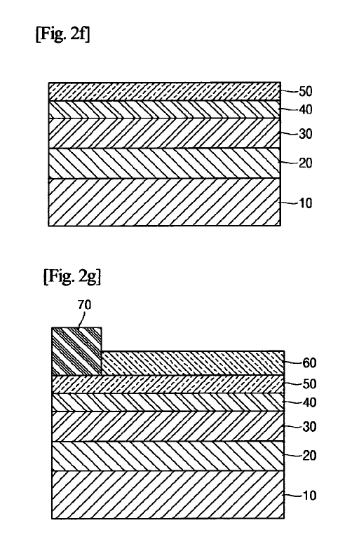

A method of manufacturing a CZTS solar cell, a CIS solar cell, and a CIGS solar cell having the foregoing configuration according to the present invention will be described below with reference to FIG. 1 and FIGS. 2A through 2G.

Referring to FIG. 2A, a substrate 10 is first provided. The substrate 10 may be formed of glass, ceramic, or metal.

As shown in FIG. 2B, a molybdenum thin film 20 is formed on the substrate 10 as a rear electrode. The molybdenum thin film 20 may be formed by a sputtering process.

Referring to FIG. 2C, a precursor layer 30a for forming a light absorption layer (see 30 in FIG. 1) is formed on the molybdenum thin film 20.

In the process of forming the precursor layer 30a for manufacturing a CZTS solar cell, a stack structure formed of a copper (Cu) layer, a zinc (Zn) layer, a tin (Sn) layer, and a sulfur (S) layer may be formed, or a single layer formed of a compound of copper, zinc, tin, and sulfur may be formed on the molybdenum thin film 20.

Meanwhile, in the process of forming the precursor layer 30a for manufacturing a CIS solar cell, a stack structure formed of a copper layer, an indium layer, and a selenium layer (or a sulfur layer) may be formed, or a single layer formed of a compound of copper, indium, and selenium (or sulfur) may be formed on the molybdenum thin film 20.

Also, in the process of forming the precursor layer 30a for manufacturing a CIGS solar cell, a stack structure formed of a copper layer, an indium layer, a gallium layer, and a selenium layer (or a sulfur layer) may be formed, or a single layer formed of a compound of copper, indium, gallium, and selenium or sulfur may be formed on the molybdenum thin film 20.

The stack structure of elements or a single layer for forming a light absorption layer is formed on the molybdenum thin film 20 and the light absorption precursor layer 30a is then formed by performing a sputtering process or a co-evaporation process.

Referring to FIG. 2D, a diffusion barrier layer 30b is formed on the light absorption precursor layer 30a. The diffusion barrier layer 30b may be formed through a physical vapor deposition (PVD) method or a chemical vapor deposition (CVD) method.

Thereafter, a crystallization operation of the light absorption precursor layer 30a is performed to form a light absorption layer 30.

As described above, the substrate 10 may be formed of glass. Also, sulfur, one of components (Cu—Zn—Sn—S) of the light absorption precursor layer 30a for a CZTS solar cell is a volatile element.

Therefore, in the case that a heat treatment process is performed for the crystallization of the light absorption precursor layer 30a, deformation of the glass substrate 10 may be generated due to heat. Also, sulfur may be volatized in the light absorption precursor layer 30a during the heat treatment process, and thus, a compositional ratio of the components constituting the light absorption precursor layer 30a may be changed.

The crystallization operation of the light absorption precursor layer 30a may be performed by using a process (or method) able to minimize the generation of heat in order to prevent such limitations, that is, the generation of deformation of the substrate 10 and the volatilization of sulfur due to heat.

Meanwhile, selenium and sulfur, components of the light absorption precursor layer 30a for a CIS solar cell or a CIGS solar cell are volatile elements. Therefore, in the case that a heat treatment process is performed for the crystallization of the light absorption precursor layer 30a, deformation of the glass substrate 10 may be generated due to heat. Also, sulfur or selenium may be volatized in the light absorption precursor layer 30a during the heat treatment process, and thus, a compositional ratio of the components constituting the light absorption precursor layer 30a may be changed.

The crystallization operation of the light absorption precursor layer 30a may be performed by using a process (or method) able to minimize the generation of heat in order to prevent the generation of deformation of the glass substrate 10 and the volatilization of selenium or sulfur due to heat.

In the present invention, the crystallization operation of the light absorption precursor layer 30a may be performed through an electron beam irradiation process in consideration of the foregoing.

In the case that the electron beam irradiation process different from the high-temperature heat treatment process is performed, an amount of heat able to minimize the deformation of the substrate and the volatilization of the components of the light absorption precursor layer is not generated and thus, the light absorption layer 30 may be formed while the components of the light absorption precursor layer 30a are crystallized in a state in which the deformation of the substrate 10 and the volatilization of the components of the light absorption precursor layer 30a are not generated (see FIG. 2E).

Through the foregoing processes, the light absorption layer 30 becomes a semiconductor layer having improved crystallinity.

Referring to FIG. 2F, the diffusion barrier layer 30b is removed through a dry or wet etching process to expose the light absorption layer 30. A buffered oxide etchant (BOE, wet etching) solution or fluorinated gas (dry etching) may be used in the etching process for removing the diffusion barrier layer 30b.

Thereafter, a buffer layer 40 is formed on the light absorption layer 30 and a window layer 50 is formed on the buffer layer 40.

As described above, since the light absorption layer 30 and the window layer 50 have a large difference in their energy bandgaps, a good p-n junction may be difficult to be formed. Therefore, the buffer layer 40 formed of a material having a bandgap between those of the light absorption layer 30 and the window layer 50 (e.g., cadmium sulfide having an energy bandgap of 2.46 eV) may be formed between the light absorption layer 30 and the window layer 50.

The cadmium sulfide buffer layer is formed through a chemical bath deposition method and may have a thickness of about 500 Å. A good p-n junction may be formed between the light absorption layer 30 and the window layer 50 due to the buffer layer 40.

The window layer 50 as an n-type semiconductor forms a p-n junction with the light absorption layer 30 and functions as a front transparent electrode of a solar cell. Therefore, the window layer 50 may be formed of a material having high optical transmittance and excellent electrical conductivity, e.g., zinc oxide (ZnO). Zinc oxide has an energy bandgap of about 3.3 eV and has a degree of optical transmission of 80% or more.

Referring to FIG. 2G, for example, an anti-reflective layer 60 is formed on the window layer 50 through a sputtering process and some area of the anti-reflective layer 60 is patterned, and a grid electrode 70 as an upper electrode is then formed in the patterned area.

Magnesium fluoride (MgF₂) is used as a material for the anti-reflective layer 60 decreasing a reflective loss of the sunlight incident on the solar cell. The grid electrode 70 collecting current on a surface of the solar cell is formed of aluminum (Al) or nickel/aluminum (Ni/Al).

Hereinafter, a crystallization process of a Cu(InGa)Se₂ precursor layer, as an example of a CIGS precursor layer according to the present invention, using an electron beam irradiation process will be described in detail.

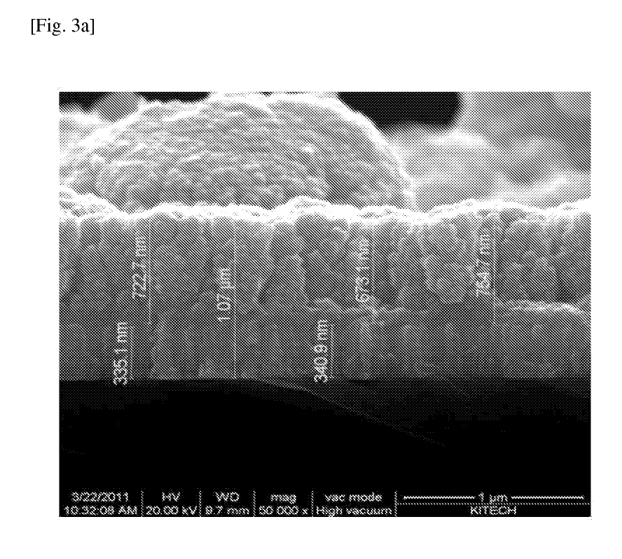

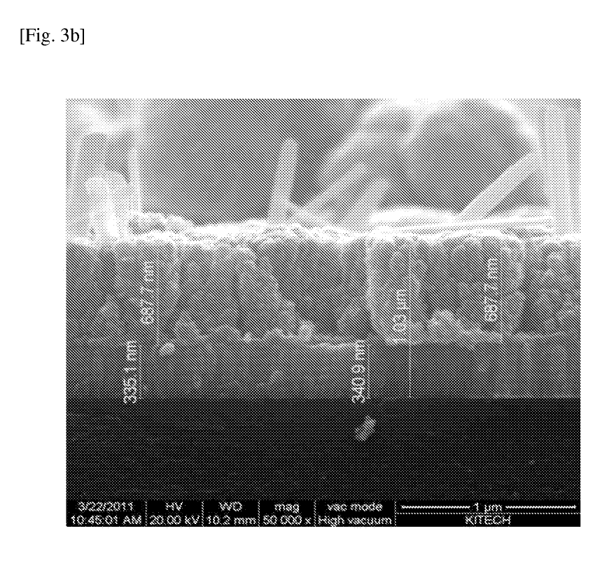

FIGS. 3A and 3B are scanning electron microscope (SEM) micrographs showing a Cu(InGa)Se₂ precursor layer formed on a glass substrate, in which FIG. 3A is a SEM micrograph of the Cu(InGa)Se₂ precursor layer before irradiation with an electron beam and FIG. 3B is a SEM micrograph of the Cu(InGa)Se₂ precursor layer after the irradiation with an electron beam.

A rear electrode was formed on a surface of the glass substrate by using molybdenum and a Cu(InGa)Se₂ precursor layer was formed on the surface of the glass substrate including the molybdenum electrode. FIG. 3A is a SEM micrograph of the Cu(InGa)Se₂ precursor layer formed on the glass substrate and it may be understood that a plurality of particles exists on the Cu(InGa)Se₂ precursor layer.

Resistance and carrier concentration of the Cu(InGa)Se₂ precursor layer were measured by using a hall effect measurement system and the results thereof are presented below.

Resistance: 2×10³ ohm, carrier concentration: 7×10²¹/cm³

Hereinafter, the Cu(InGa)Se₂ precursor layer was irradiated with an electron beam for 20 seconds. FIG. 3B is a SEM micrograph of the Cu(InGa)Se₂ precursor layer formed on the glass substrate after the irradiation with an electron beam and it may be understood that the particles existed on the Cu(InGa)Se₂ precursor layer were separated and removed.

Resistance and carrier concentration of the Cu(InGa)Se₂ precursor layer were measured by using a hall effect measurement system and the results thereof are presented below.

Resistance: 1×10² ohm, carrier concentration: 4×10²²/cm³

It may be understood that the Cu(InGa)Se₂ precursor layer crystallized by an electron beam may have excellent electrical characteristics in terms of the fact that electrical performance of the Cu(InGa)Se₂ precursor layer is inversely proportional to resistance and proportional to carrier concentration.

Intensities for the Cu(InGa)Se₂ precursor layer before being exposed to an electron beam and the Cu(InGa)Se₂ precursor layer exposed to an electron beam for 20 seconds were measured by using a X-ray diffraction system.

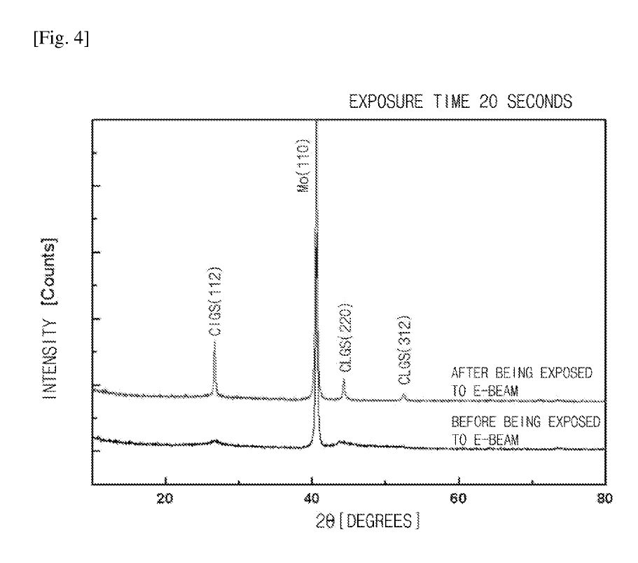

FIG. 4 is a graph showing the intensity of the Cu(InGa)Se₂ precursor layer without being exposed to an electron beam and the intensity of the Cu(InGa)Se₂ precursor layer after being exposed to an electron beam for 20 seconds according to an angle.

With respect to the Cu(InGa)Se₂ precursor layer without being exposed to an electron beam, an intensity peak was not shown in all regions except the molybdenum electrode. However, with respect to the Cu(InGa)Se₂ precursor layer after being exposed to an electron beam for 20 seconds, intensity peaks were measured in four regions including the molybdenum electrode.

The graph shows that the Cu(InGa)Se₂ precursor layer in an amorphous state before being exposed to an electron beam was crystallized after being exposed to an electron beam for 20 seconds. That is, it means that the amorphous Cu(InGa)Se₂ precursor layer was crystallized by using an electron beam instead of using high-temperature heat.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present disclosure as set forth in the following claims.

1. A method of manufacturing a solar cell, the method comprising:
providing a substrate;
forming a rear electrode on the substrate;
forming a precursor layer on the rear electrode;
performing a crystallization process on the precursor layer to form a light absorption layer, whereby the precursor layer is crystallized and changed to the light absorption layer;
forming a buffer layer on the light absorption layer;
forming a window layer on the buffer layer and forming an anti-reflective layer on the window layer; and
patterning the anti-reflective layer to form a grid electrode in a patterned area.

2. The method as claimed in claim 1, wherein the crystallization process of the precursor layer is performed through an electron beam irradiation process.

3. The method as claimed in claim 1, wherein the substrate is formed of glass.

4. The method as claimed in claim 1, wherein the precursor layer is formed of Cu₂ZnSnS₄.

5. The method as claimed in claim 4, wherein the Cu₂ZnSnS₄ precursor layer has a multilayer structure of each component or a single layer structure formed of a compound of components.

6. The method as claimed in claim 1, wherein the precursor layer is formed of CuInSe₂, CuInS₂, Cu(InGa)Se₂, or Cu(InGa)S₂.

7. The method as claimed in claim 6, wherein a CuInSe₂ precursor layer, a CuInS₂ precursor layer, a Cu(InGa)Se₂ precursor layer, or a Cu(InGa)S₂ precursor layer has a multilayer structure of each component or a single layer structure formed of a compound of components.

8. The method as claimed in claim 1, wherein the rear electrode is formed of molybdenum (Mo).

9. The method as claimed in claim 1, wherein the precursor layer is formed by performing a sputtering process.

10. The method as claimed in claim 1, wherein the precursor layer is formed by performing a co-evaporation process.

11. A method of manufacturing a solar cell, the method comprising:
providing a substrate;
forming a rear electrode on the substrate;
forming a precursor layer on the rear electrode;
forming a diffusion barrier layer on the precursor layer;
performing a crystallization process on the precursor layer to form a light absorption layer, whereby the precursor layer is crystallized and changed to the light absorption layer;
removing the diffusion barrier layer by etching process, whereby the crystallized light absorption layer is exposed;
forming a buffer layer on the light absorption layer;
forming a window layer on the buffer layer and forming an anti-reflective layer on the window layer; and
patterning the anti-reflective layer to form a grid electrode in a patterned area.

12. The method as claimed in claim 11, wherein the crystallization process of the precursor layer is performed through an electron beam irradiation process.

13. The method as claimed in claim 11, wherein the substrate is formed of glass.

14. The method as claimed in claim 11, wherein the precursor layer is formed of Cu₂ZnSnS₄.

15. The method as claimed in claim 14, wherein the Cu₂ZnSnS₄ precursor layer has a multilayer structure of each component or a single layer structure formed of a compound of components.

16. The method as claimed in claim 11, wherein the precursor layer is formed of CuInSe₂, CuInS₂, Cu(InGa)Se₂, or Cu(InGa)S₂.

17. The method as claimed in claim 16, wherein a CuInSe₂ precursor layer, a CuInS₂ precursor layer, a Cu(InGa)Se₂precursor layer, or a Cu(InGa)S₂ precursor layer has a multilayer structure of each component or a single layer structure formed of a compound of components.

18. The method as claimed in claim 11, wherein the rear electrode is formed of molybdenum (Mo).

19. The method as claimed in claim 11, wherein the precursor layer is formed by performing a sputtering process.

20. The method as claimed in claim 11, wherein the precursor layer is formed by performing a co-evaporation process.
